(19) United States
(12) Patent Application Publication
(10) Pub. No.: US 2024/0113014 A1
(43) Pub. Date: Apr. 4, 2024

(54) Techniques For Shifting Signal Transmission To Compensate For Defects In Pads In Integrated Circuits

(71) Applicant: Altera Corporation, San Jose, CA (US)

(72) Inventors: Krishna Bharath Kolluru, Portland, OR (US); Atul Maheshwari, Portland, OR (US); Mahesh Kumashikar, Bangalore (IN); Md Altaf Hossain, Portland, OR (US); Ankireddy Nalamalpu, Portland, OR (US); Jeffrey Chromczak, Toronto (CA)

(73) Assignee: Altera Corporation, San Jose, CA (US)

(21) Appl. No.: 18/539,193

(22) Filed: Dec. 13, 2023

(51) Int. Cl. H01L 23/525; H01L 23/528; H01L 27/105

(52) U.S. Cl. CPC H01L 23/525; H01L 23/528; H01L 27/105

(57) ABSTRACT

An integrated circuit includes first external conductive pads, second external conductive pads, and third external conductive pads. The second external conductive pads are between the first external conductive pads and the third external conductive pads. Repair group circuitry is configurable to shift signal transmission away from one of the first external conductive pads to one of the third external conductive pads if the one of the first external conductive pads has a defect.

### TECHNICAL FIELD

The present disclosure relates to electronic integrated circuits, and more particularly, to techniques for shifting transmission of signals to compensate for defects that affect external pads in integrated circuits.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can used in application acceleration tasks in a datacenter and can be reprogrammed during datacenter operation to perform different tasks.

### BRIEF DESCRIPTION OF DRAWINGS

FIG. 1 is a diagram that depicts an example of a portion of an integrated circuit die that includes external conductive pads arranged in repair groups.

FIG. 2 is a diagram that depicts examples of circuits that can be used to implement the repair groups disclosed herein.

FIG. 3 is a diagram that depicts an example of a portion of another integrated circuit die that includes external conductive pads arranged in repair groups.

FIG. 4 is a diagram of an illustrative example of a configurable integrated circuit (IC).

FIG. 5 illustrates a block diagram of a system that can be used to implement a circuit design to be programmed onto a programmable logic device using design software.

FIG. 6 is a diagram that depicts an example of a programmable logic device that includes a fabric die and a base die that are connected to one another via microbumps.

FIG. 7 is a block diagram illustrating a computing system configured to implement one or more aspects of the embodiments described herein.

### DETAILED DESCRIPTION

In many types of electronic devices, a large defect can occur that affects several external conductive pads of an integrated circuit die during the manufacturing process. A manufacturing defect that is large (e.g., 54×54 micrometers) with respect to the pitch between the pads (e.g. 9×9 micrometers) can result in a significant yield loss for the integrated circuit dies (e.g., about 12%), even with repair techniques that add overhead in area (e.g., about 12.5%). Many types of previously known techniques for repairing manufacturing defects that affect conductive pads in integrated circuit dies are difficult to modify for larger defects. As a result, it can be difficult to improve yield for batches of integrated circuit dies having a significant amount of large manufacturing defects.

According to some examples disclosed herein, techniques are provided for manufacturing an integrated circuit die that increase the resiliency of the integrated circuit die to large manufacturing defects that affect external conductive pads of the integrated circuit die. According to these techniques, redundant external conductive pads are provided in an integrated circuit die. If a manufacturing defect disables one or more external conductive pads in the integrated circuit die, circuitry in the integrated circuit die shifts input and/or output signals to one or more of the redundant external conductive pads to replace the disabled external conductive pads. Thus, the redundant external conductive pads are used to repair the integrated circuit die and to restore full input/output signal transmission to a group of the external conductive pads. These techniques can provide a scalable redundancy architecture for external conductive pads and conductive bumps with low repair overhead and significantly reduced physical design complexity. These techniques can provide flexibility in scaling pad architectures to resolve large defect sizes and can resolve large defect sizes in a pad limited circuit design for an integrated circuit die.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

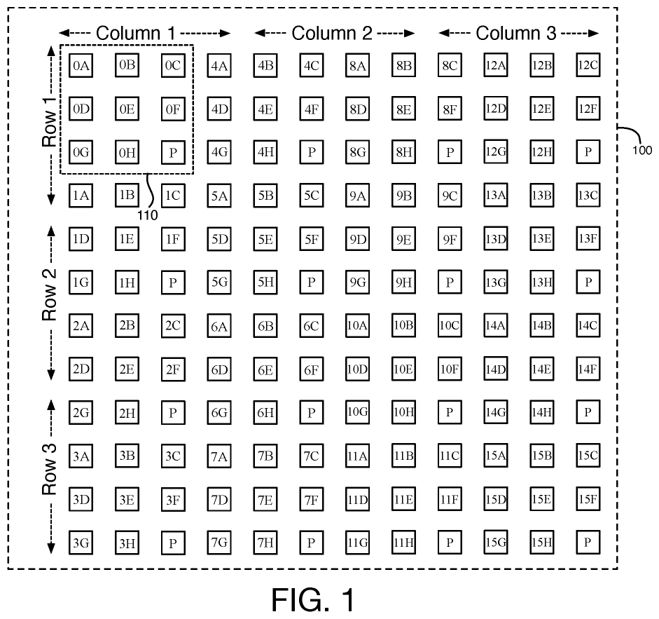

FIG. 1 is a diagram that depicts an example of a portion of an integrated circuit die 100 that includes external conductive pads. IC die 100 is also referred to herein as IC 100. IC 100 can be any type of integrated circuit (IC), such as a configurable IC (e.g., a field programmable gate array (FPGA) or programmable logic device), a microprocessor IC, a graphics processing unit IC, a memory IC, an application specific IC, a transceiver IC, a memory IC, etc.

Figure (FIG. 1 shows a top down (or bottom up) view of an external surface of the portion of integrated circuit (IC) die 100. The external conductive pads are exposed at the external surface of IC 100 for connecting internal circuitry of IC 100 to other devices through conductive connections, such as conductive balls or bumps. The external conductive pads are shown in FIG. 1 as squares. However, in other implementations, external conductive pads arranged according to the techniques disclosed herein can have any desired shape, such circular, oval, or rectangular shapes.

FIG. 1 illustrates 144 external conductive pads (also referred to herein simply as pads or conductive pads) that are arranged in three vertical columns (Column 1-Column 3) and three horizontal rows (Row 1-Row 3). Each column includes 4 sub-columns of pads, and each row includes 4 sub-rows of pads. Although, it should be understood that the techniques disclosed herein apply to integrated circuits having any number of external conductive pads in any arrangement. The external conductive pads can be coupled to any internal circuitry in IC 100.

The 144 external conductive pads include 128 external conductive pads that route signals (e.g., control signals, data signals, or clock signals) and 16 external conductive pads that route one or more power supply voltages. The external conductive pads that route one or more power supply voltages are labeled with a P in FIG. 1 and are referred to herein as power pads. The 128 external conductive pads that route signals are labeled 0A-0H, 1A-1H, 2A-2H, 3A-3H, 4A-4H, 5A-5H, 6A-6H, 7A-7H, 8A-8H, 9A-9H, 10A-10H, 11A-11H, 12A-12H, 13A-13H, 14A-14H, and 15A-15H. These 128 external conductive pads are referred to as signal pads. The letters A-H correspond to 8 different repair groups of the signal pads. The numbers 1-15 correspond to signal pads for routing 14 different bits and 1 repair bit in each repair group. As an example, the first repair group includes signal pads 0A, 1A, 2A, 3A, 4A, 5A, 6A, 7A, 8A, 9A, 10A, 11A, 12A, 13A, 14A, and 15A, where 0A-14A are signal pads for routing 14 bits, and 15A is a signal pad for routing the repair bit. As another example, the second repair group includes signal pads 0B, 1B, 2B, 3B, 4B, 5B, 6B, 7B, 8B, 9B, 10B, 11B, 12B, 13B, 14B, and 15B, where 0B-14B are signal pads for routing 14 bits, and 15B is a signal pad for routing the repair bit. Signal pads 15A-15H are redundant (or spare) signal pads for the repair bits.

A manufacturing defect (e.g., a short or an open circuit) can, for example, affect (e.g., disable) one or more external conductive pads in IC 100. If a manufacturing defect disables one of the signal pads shown in FIG. 1, the input or output signal for the disabled signal pad is shifted to or from another signal pad within the same repair group. A defect affecting a signal pad within a repair group can be compensated for by shifting other input or output signals within the repair group to (or from) other signal pads within the same repair group, with the last input or output signal being shifted to (or from) the redundant signal paid (i.e., one of signal pads 15A-15H) within the same repair group.

FIG. 1 illustrates the maximum size defect 110 that can be repaired (i.e., compensated for) in IC 100 using the repair groups. In this example, defect 110 disables all 8 of the signal pads 0A-0H and one power pad P. The signals that would have been routed through the disabled pads 0A-0H and P are instead shifted to be routed through signal pads 1A-1H and the power pad P in Row 2, Column 1, respectively. Each of the disabled pads 0A-0H and P is replaced with a respective pad 1A-1H and P in the same repair group.

In IC 100, a defect affecting a signal pad in any one of the repair groups can be compensated for by shifting the input/output signal that would have been routed through the disabled signal pad to another signal pad in the same repair group and by shifting other input/output signals within the repair group to other signal pads within the same repair group. The last input/output signal in the repair group is shifted to the redundant signal pad within the same repair group. If multiple defects disable signal pads in different repair groups in IC 100, with the defects disabling only one signal pad in each repair group, then each of the defects is compensated for by shifting the input/output signal that would have been routed through the disabled signal pad to another signal pad within the same repair group. As an example, if defects disable signal pads 1E, 4C, and 11G, with the defects disabling only one signal pad in each repair group, then the input/output signals that would have been routed through signal pads 1E, 4C, and 11G are instead re-routed through signal pads 2E, 5C, and 12G, respectively. Also, in this example, the input/output signals that would have been routed through signal pads 2E-14E, 5C-14C, and 12G-14G are instead re-rerouted through signal pads 3E-15E, 6C-15C, and 13G-15G, respectively.

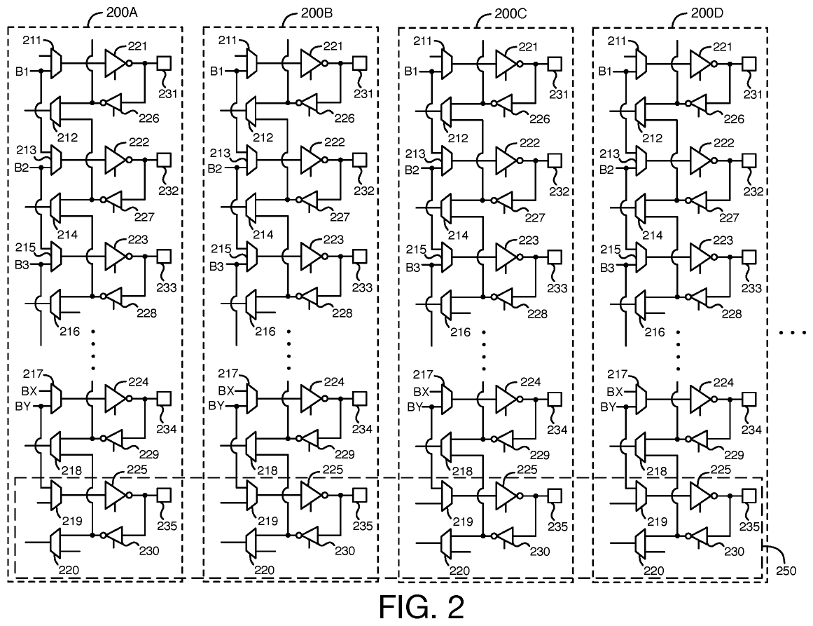

FIG. 2 is a diagram that depicts examples of circuits that can be used to implement the repair groups disclosed herein. FIG. 2 illustrates 4 repair group circuits 200A-200D in an integrated circuit, such as IC 100, as examples. Although, it should be understood that integrated circuits, such as IC 100, can have any appropriate number of the repair group circuits. The repair group circuits are collectively referred to as repair groups 200 in the example of FIG. 2. IC 100, for example, can have 9 of the repair groups 200 (A-H and P) shown in FIG. 2.

Each of the repair groups 200 includes output multiplexer circuits 211, 213, 215, 217, and 219. Each of the repair groups 200 also includes input multiplexer circuits 212, 214, 216, 218, and 220. Each of the repair groups 200 also includes tri-state output buffer circuits 221-225, tri-state input buffer circuits 226-230, and external conductive pads 231-235. Although five pads 231-235, five output buffer circuits 221-225, five input buffer circuits 226-230, 5 output multiplexer circuits, and 5 input multiplexer circuits are shown in each repair group 200 in FIG. 2, each repair group can have any number of these circuits that are coupled as shown in FIG. 2.

As a specific example, in the implementation shown in FIG. 1, each repair group 200 can have 16 signal pads (e.g., signal pads 0A-15A), 16 output buffer circuits, 16 input buffer circuits, 16 output multiplexer circuits, and 16 input multiplexer circuits that are coupled as shown in FIG. 2 to transmit the 15 bits and 1 repair bit in each repair group. According to this example, pads 231-235 in repair group circuit 200A correspond to pads 0A, 1A, 2A, 14A, and 15A, respectively. Also, in this example, pads 231-235 in repair group circuit 200B correspond to pads 0B, 1B, 2B, 14B, and 15B, respectively. Further, in this example, pads 231-235 in repair group circuit 200C correspond to pads 0C, 1C, 2C, 14C, and 15C, respectively.

The tri-state output buffer circuits 221-225 can be individually disabled or enabled to drive output signals from multiplexer circuits 211, 213, 215, 217, and 219 to pads 231-235, respectively. The tri-state input buffer circuits 226-230 can be individually disabled or enabled to drive input signals from pads 231-235, respectively, to multiplexer circuits 212, 214, 216, 218, and 220, as shown in FIG. 2. The multiplexer circuits 219-220, the buffer circuits 225 and 230, and the pad 235 in the repair groups 200 are redundant circuitry 250 that are used to compensate for defects affecting signal pads within the repair groups.

If the buffer circuits 221-225 in one of the repair groups 200 are configured to drive output signals to the signal pads, and none of the signal pads in that repair group are affected by defects, then multiplexer circuits 211, 213, 215, and 217 are configured to provide signals B1, B2, B3, and BY for transmission outside the IC through output buffer circuits 221, 222, 223, and 224 and pads 231, 232, 233, and 234, respectively. Pad 235 is unused when pads 231-234 are unaffected by defects. Signal BX is driven by an output buffer circuit through a signal pad that are not shown in FIG. 2.

For any of the repair groups 200 that are configured to transmit output signals, a defect affecting one signal pad within the repair group can be compensated for by shifting the subsequent output signals within the repair group to other signal pads within the same repair group, with the last output signal being shifted to the redundant signal paid 235 in redundant circuitry 250 within the same repair group. As an example, if a defect (e.g., an open circuit or short) disables pad 231 in any of the repair groups 200, and the buffer circuits 221-225 in that repair group are configured to drive output signals to the signal pads, then multiplexer circuits 213, 215, 217, and 219 are configured to provide the output signals B1, B2, BX, and BY for transmission outside the IC through output buffer circuits 222, 223, 224, and 225 and pads 232, 233, 234, and 235, respectively. Thus, redundant pad 235 is used to transmit one of the output signals. Signal B3 is selected by a multiplexer circuit and driven by an output buffer circuit through a signal pad in the repair group that are not shown in FIG. 2.

As another example, if a defect disables pad 234 in any of the repair groups 200, and the buffer circuits 221-225 in that repair group are configured to drive output signals to the signal pads, then multiplexer circuit 219 is configured to provide output signal BY for transmission outside the IC through output buffer circuit 225 and pad 235. The other multiplexer circuits 211, 213, 215, etc. remain configured to provide the output signals B1, B2, B3, etc. for transmission outside the IC through output buffer circuits 221, 222, 223 etc. and pads 231, 232, 233, etc., respectively.

If the buffer circuits 226-230 in one of the repair groups 200 are configured to drive input signals from the signal pads 231-235 to other circuitry in the IC, and none of the signal pads in that repair group are affected by defects, then multiplexer circuits 212, 214, 216, and 218 are configured to provide input signals that are received from outside the IC through signal pads 231, 232, 233, and 234 and input buffer circuits 226, 227, 228, and 229, respectively, to other circuitry in the IC.

For any of the repair groups 200 that are configured to transmit input signals, a defect affecting one signal pad within the repair group can be compensated for by shifting the subsequent input signals within the repair group from other signal pads within the same repair group, with the last input signal being shifted from the redundant signal paid 235 in redundant circuitry 250 within the same repair group. As an example, if a defect (e.g., an open circuit or short) disables pad 231 in any of the repair groups 200, and the buffer circuits 226-230 in that repair group are configured to drive input signals from the signal pads, then multiplexer circuit 212 is configured to provide an input signal received from outside the IC through signal pad 232 and buffered by input buffer circuit 227 to other circuitry in the IC. Also, multiplexer circuit 214 is configured to provide an input signal received from outside the IC through signal pad 233 and buffered by input buffer circuit 228 to other circuitry in the IC. Also, multiplexer circuit 218 is configured to provide an input signal received from outside the IC through signal pad 235 and buffered by input buffer circuit 230 to other circuitry in the IC. An input signal received through a signal pad between pads 233 and 234 and an input buffer circuit between buffer circuits 228 and 224 in the same repair group that are not shown in FIG. 2 is selected by multiplexer circuit 216 and provided to other circuitry in the IC in this example.

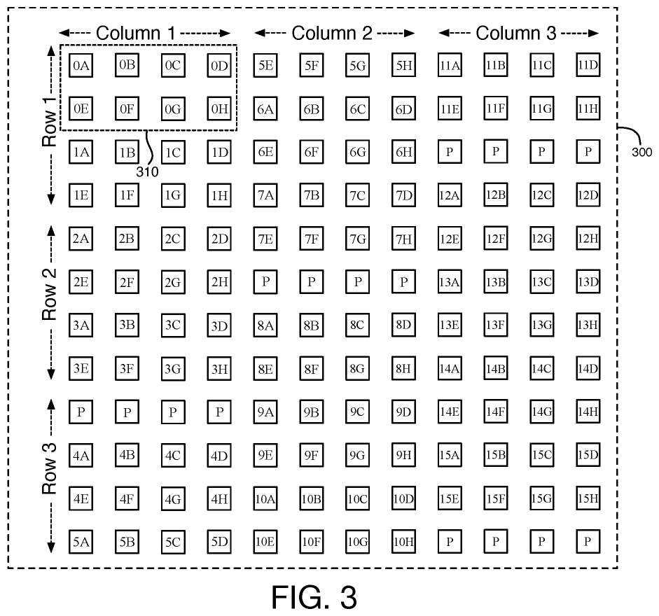

FIG. 3 is a diagram that depicts an example of a portion of another integrated circuit die 300 that includes external conductive pads. IC die 300 is also referred to herein as IC 300. IC 300 can be any type of integrated circuit (IC), such as a configurable IC (e.g., a field programmable gate array (FPGA) or programmable logic device), a microprocessor IC, a graphics processing unit IC, a memory IC, an application specific IC, a transceiver IC, a memory IC, etc.

FIG. 3 shows a top down (or bottom up) view of an external surface of the portion of integrated circuit (IC) die 300. The external conductive pads are exposed at the external surface of IC 300 for connecting internal circuitry of IC 300 to other devices through conductive connections, such as conductive balls or bumps. The external conductive pads are shown in FIG. 3 as squares as examples. In other implementations, external conductive pads arranged according to the techniques disclosed herein can have any shape, such circular, oval, or rectangular shapes.

FIG. 3 illustrates 144 external conductive pads that are arranged in three vertical columns (Column 1-Column 3) and three horizontal rows (Row 1-Row 3). Each column includes 4 sub-columns of pads, and each row includes 4 sub-rows of pads. Although, it should be understood that the techniques disclosed herein apply to integrated circuits having any number of external conductive pads in any arrangement. The external conductive pads can be coupled to any circuitry in IC 300.

The 144 external conductive pads of FIG. 3 include 128 external conductive pads that route signals (e.g., control signals, data signals, or clock signals) and 16 external conductive pads that route one or more power supply voltages. The external conductive pads that route one or more power supply voltages are labeled with a P in FIG. 3 and are referred to herein as power pads. The 128 external conductive pads that route signals are labeled 0A-0H, 1A-1H, 2A-2H, 3A-3H, 4A-4H, 5A-5H, 6A-6H, 7A-7H, 8A-8H, 9A-9H, 10A-10H, 11A-11H, 12A-12H, 13A-13H, 14A-14H, and 15A-15H. These 128 external conductive pads are referred to as signal pads. The letters A-H correspond to 8 different repair groups of the signal pads. The numbers 1-15 correspond to signal pads for routing 14 different bits and 1 repair bit in each repair group. As an example, the first repair group includes signal pads 0A, 1A, 2A, 3A, 4A, 5A, 6A, 7A, 8A, 9A, 10A, 11A, 12A, 13A, 14A, and 15A, where 0A-14A are signal pads for routing 14 bits, and 15A is a signal pad for routing the repair bit. As another example, the fifth repair group includes signal pads 0E, 1E, 2E, 3E, 4E, 5E, 6E, 7E, 8E, 9E, 10E, 11E, 12E, 13E, 14E, and 15E, where 0E-14E are signal pads for routing 14 bits, and 15E is a signal pad for routing the repair bit. Signal pads 15A-15H are redundant (or spare) signal pads for the repair bits.

FIG. 3 illustrates the maximum size defect 310 that can be compensated for in IC 300 using the repair groups. In this example, defect 310 disables all 8 of the signal pads 0A-0H. The input or output signals that would have been routed through the disabled pads 0A-0H are instead shifted to be routed through signal pads 1A-1H in Row 2, Column 1, respectively, using the circuitry in the repair groups 200 disclosed herein with respect to FIG. 2. Each of the disabled pads 0A-0H is replaced with a respective one of pads 1A-1H by reconfiguring a respective multiplexer circuit in the same respective repair group, as disclosed herein with respect to FIG. 2.

In IC 300, a defect affecting a signal pad in any one of the repair groups can be compensated for by shifting the input/output signal that would have been routed through the disabled signal pad to another signal pad in the same repair group and by shifting other input/output signals within the repair group to other signal pads within the same repair group, for example, using repair groups 200 of FIG. 2. The last input/output signal in the repair group is shifted to the redundant signal pad within the same repair group in redundant circuitry 250. As an example, if defects disable signal pads 2B, 6H, and 12F of FIG. 3, with each defect disabling only one signal pad in each repair group, then the input/output signals that would have been routed through signal pads 2B, 6H, and 12F are instead re-routed through signal pads 3B, 7H, and 13F, respectively, using repair groups 200. Also, in this example, the input/output signals that would have been routed through signal pads 3B-14B, 7H-14H, and 13F-14F are instead re-rerouted through signal pads 4B-15B, 8H-15H, and 14F-15F, respectively, using repair groups 200.

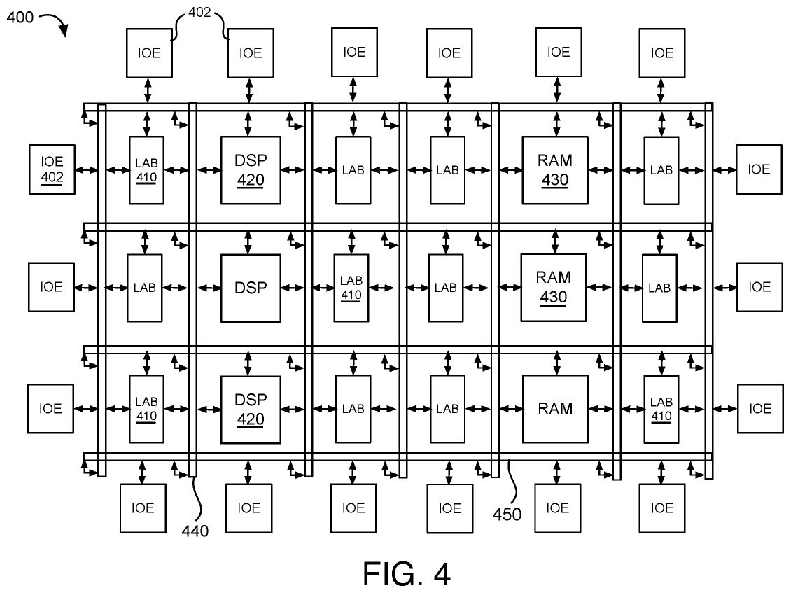

FIG. 4 is a diagram of an illustrative example of a configurable integrated circuit (IC) 400. Configurable IC 400 is an example of an IC that can include the pads and circuitry disclosed herein with respect to FIGS. 1, 2 and/or 3. As shown in FIG. 4, the configurable integrated circuit 400 includes a two-dimensional array of configurable functional blocks, including logic array blocks (LABs) 410 and other functional blocks, such as random access memory (RAM) blocks 430 and digital signal processing (DSP) blocks 420, for example. Configurable functional blocks, such as LABs 410, can include smaller configurable regions (e.g., configurable logic elements, configurable logic blocks, or adaptive logic modules) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

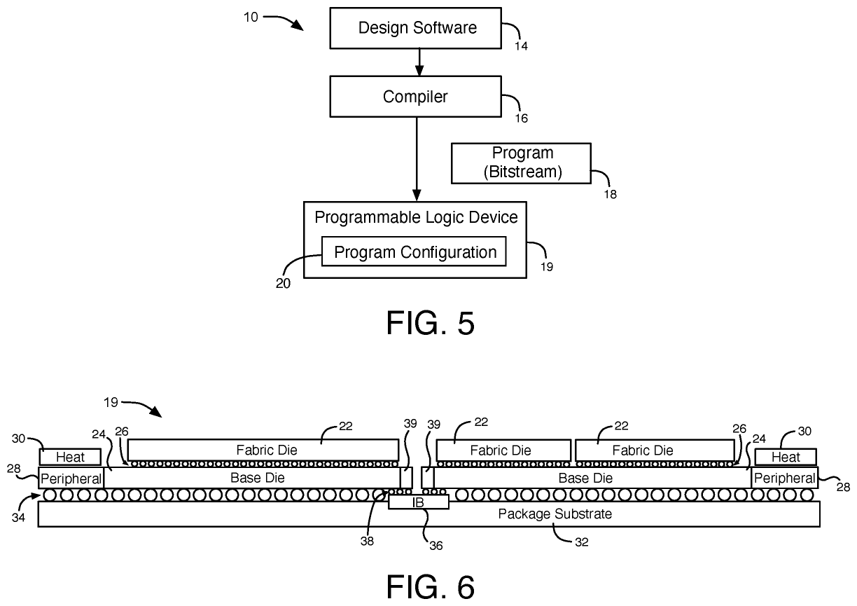

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

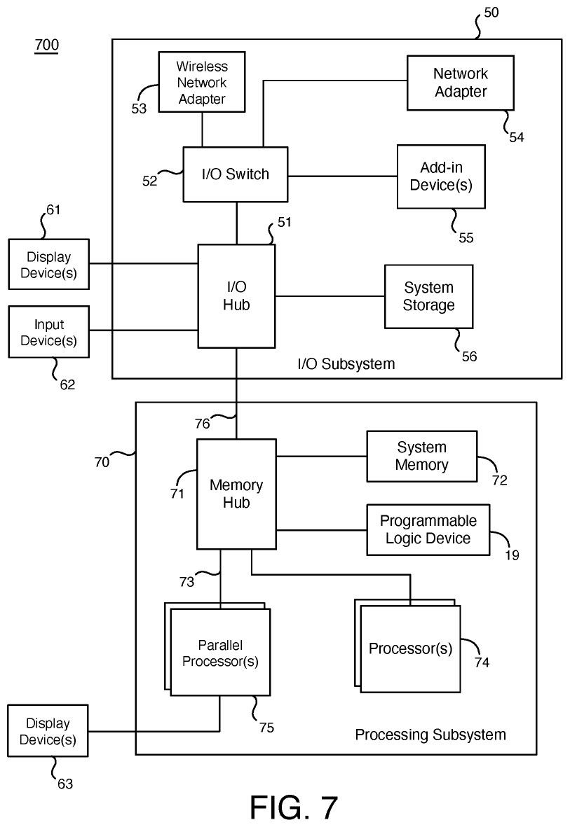

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising first external conductive pads; second external conductive pads; third external conductive pads, wherein the second external conductive pads are between the first external conductive pads and the third external conductive pads; and repair group circuitry configurable to shift first signal transmission away from a first one of the first external conductive pads to a first one of the third external conductive pads.

In Example 2, the integrated circuit of Example 1 further comprises: fourth external conductive pads, wherein the fourth external conductive pads are between the second external conductive pads and the third external conductive pads.

In Example 3, the integrated circuit of any one of Examples 1-2 can optionally include, wherein the first external conductive pads and the second external conductive pads are arranged in at least a 2 by 2 array.

In Example 4, the integrated circuit of any one of Examples 1-3 can optionally include, the repair group circuitry is further configurable to shift second signal transmission away from a second one of the first external conductive pads to a second one of the third external conductive pads.

In Example 5, the integrated circuit of any one of Examples 1-4 can optionally include, wherein the first external conductive pads, the second external conductive pads, and fourth external conductive pads on a surface of the integrated circuit are arranged in at least a 3 by 3 array.

In Example 6, the integrated circuit of any one of Examples 1-5 can optionally include, wherein the repair group circuitry is further configurable to shift second and third signal transmission away from second and third ones of the first external conductive pads to second and third ones of the third external conductive pads.

In Example 7, the integrated circuit of any one of Examples 1-6 can optionally include, wherein the repair group circuitry is further configurable to individually shift any signal transmission away from any of the first external conductive pads to a corresponding one of the third external conductive pads.

In Example 8, the integrated circuit of any one of Examples 1-7 can optionally include, wherein the repair group circuitry comprises a multiplexer that is configurable to select a signal for transmission through the first one of the third external conductive pads.

In Example 9, the integrated circuit of any one of Examples 1-8 can optionally include, wherein the repair group circuitry comprises a multiplexer that is configurable to select a signal received from the first one of the third external conductive pads.

In Example 10, the integrated circuit of any one of Examples 1-9 can optionally include, wherein the first one of the first external conductive pads and the first one of the third external conductive pads are coupled to a first defect repair circuit in the repair group circuitry comprising multiplexers configurable to shift the first signal transmission away from the first one of the first external conductive pads to the first one of the third external conductive pads.

Example 11 is a method for shifting transmission in an integrated circuit, wherein the method comprises: configuring a first repair group circuit to shift transmission of a first signal from a first one of external pads to a second one of the external pads, wherein a third one of the external pads is between the first and the second ones of the external pads; and configuring a second repair group circuit to shift transmission of a second signal from a fourth one of the external pads to a fifth one of the external pads, wherein a sixth one of the external pads is between the fourth and the fifth ones of the external pads.

In Example 12, the method of Example 11 can optionally include, wherein the first, the third, the fourth, and the sixth ones of the external pads are arranged in a 2 by 2 array on a surface of the integrated circuit.

In Example 13, the method of any one of Examples 11-12 further comprises: configuring a third repair group circuit to shift transmission of a third signal from a seventh one of the external pads to an eighth one of the external pads, wherein a ninth one of the external pads is between the seventh and the eighth ones of the external pads.

In Example 14, the method of Example 13 can optionally include, wherein the first, the third, the fourth, the sixth, the seventh, and the ninth ones of the external pads and additional ones of the external pads are arranged in a 3 by 3 array on a surface of the integrated circuit.

In Example 15, the method of any one of Examples 11-14 further comprises configuring the first repair group circuit to shift transmission of a third signal from the second one of the external pads to a seventh one of the external pads; and configuring the second repair group circuit to shift transmission of a fourth signal from the fifth one of the external pads to an eighth one of the external pads.

Example 16 is an integrated circuit comprising: external pads; a first repair group circuit configurable to shift transmission of a first signal from a first one of the external pads to a second one of the external pads, wherein a third one of the external pads is between the first and the second ones of the external pads; and a second repair group circuit configurable to shift transmission of a second signal from a fourth one of the external pads to a fifth one of the external pads, wherein a sixth one of the external pads is between the fourth and the fifth ones of the external pads.

In Example 17, the integrated circuit of Example 16 can optionally include, wherein the first, the third, the fourth, and the sixth ones of the external pads are arranged in a 2 by 2 array on a surface of the integrated circuit.

In Example 18, the integrated circuit of any one of Examples 16-17 further comprises: a third repair group circuit configurable to shift transmission of a third signal from a seventh one of the external pads to an eighth one of the external pads, wherein a ninth one of the external pads is between the seventh and the eighth ones of the external pads.

In Example 19, the integrated circuit of Example 18 can optionally include, wherein the first, the third, the fourth, the sixth, the seventh, and the ninth ones of the external pads and additional ones of the external pads are arranged in a 3 by 3 array on a surface of the integrated circuit.

In Example 20, the integrated circuit of any one of Examples 16-19 can optionally include, wherein the first repair group circuit is configurable to shift transmission of a third signal from the second one of the external pads to a seventh one of the external pads, and wherein the second repair group circuit is configurable to shift transmission of a fourth signal from the fifth one of the external pads to an eighth one of the external pads.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An integrated circuit comprising:
first external conductive pads;
second external conductive pads;
third external conductive pads, wherein the second external conductive pads are between the first external conductive pads and the third external conductive pads; and
repair group circuitry configurable to shift first signal transmission away from a first one of the first external conductive pads to a first one of the third external conductive pads.

2. The integrated circuit of claim 1 further comprising:
fourth external conductive pads, wherein the fourth external conductive pads are between the second external conductive pads and the third external conductive pads.

3. The integrated circuit of claim 1, wherein the first external conductive pads and the second external conductive pads are arranged in at least a 2 by 2 array.

4. The integrated circuit of claim 1, the repair group circuitry is further configurable to shift second signal transmission away from a second one of the first external conductive pads to a second one of the third external conductive pads.

5. The integrated circuit of claim 1, wherein the first external conductive pads, the second external conductive pads, and fourth external conductive pads on a surface of the integrated circuit are arranged in at least a 3 by 3 array.

6. The integrated circuit of claim 1, wherein the repair group circuitry is further configurable to shift second and third signal transmission away from second and third ones of the first external conductive pads to second and third ones of the third external conductive pads.

7. The integrated circuit of claim 1, wherein the repair group circuitry is further configurable to individually shift any signal transmission away from any of the first external conductive pads to a corresponding one of the third external conductive pads.

8. The integrated circuit of claim 1, wherein the repair group circuitry comprises a multiplexer that is configurable to select a signal for transmission through the first one of the third external conductive pads.

9. The integrated circuit of claim 1, wherein the repair group circuitry comprises a multiplexer that is configurable to select a signal received from the first one of the third external conductive pads.

10. The integrated circuit of claim 1, wherein the first one of the first external conductive pads and the first one of the third external conductive pads are coupled to a first defect repair circuit in the repair group circuitry comprising multiplexers configurable to shift the first signal transmission away from the first one of the first external conductive pads to the first one of the third external conductive pads.

11. A method for shifting transmission in an integrated circuit, wherein the method comprises:
configuring a first repair group circuit to shift transmission of a first signal from a first one of external pads to a second one of the external pads, wherein a third one of the external pads is between the first and the second ones of the external pads; and
configuring a second repair group circuit to shift transmission of a second signal from a fourth one of the external pads to a fifth one of the external pads, wherein a sixth one of the external pads is between the fourth and the fifth ones of the external pads.

12. The method of claim 11, wherein the first, the third, the fourth, and the sixth ones of the external pads are arranged in a 2 by 2 array on a surface of the integrated circuit.

13. The method of claim 11 further comprising:
configuring a third repair group circuit to shift transmission of a third signal from a seventh one of the external pads to an eighth one of the external pads, wherein a ninth one of the external pads is between the seventh and the eighth ones of the external pads.

14. The method of claim 13, wherein the first, the third, the fourth, the sixth, the seventh, and the ninth ones of the external pads and additional ones of the external pads are arranged in a 3 by 3 array on a surface of the integrated circuit.

15. The method of claim 11 further comprising:
configuring the first repair group circuit to shift transmission of a third signal from the second one of the external pads to a seventh one of the external pads; and
configuring the second repair group circuit to shift transmission of a fourth signal from the fifth one of the external pads to an eighth one of the external pads.

16. An integrated circuit comprising:
external pads;
a first repair group circuit configurable to shift transmission of a first signal from a first one of the external pads to a second one of the external pads, wherein a third one of the external pads is between the first and the second ones of the external pads; and
a second repair group circuit configurable to shift transmission of a second signal from a fourth one of the external pads to a fifth one of the external pads, wherein a sixth one of the external pads is between the fourth and the fifth ones of the external pads.

17. The integrated circuit of claim 16, wherein the first, the third, the fourth, and the sixth ones of the external pads are arranged in a 2 by 2 array on a surface of the integrated circuit.

18. The integrated circuit of claim 16 further comprising:
a third repair group circuit configurable to shift transmission of a third signal from a seventh one of the external pads to an eighth one of the external pads, wherein a ninth one of the external pads is between the seventh and the eighth ones of the external pads.

19. The integrated circuit of claim 18, wherein the first, the third, the fourth, the sixth, the seventh, and the ninth ones of the external pads and additional ones of the external pads are arranged in a 3 by 3 array on a surface of the integrated circuit.

20. The integrated circuit of claim 16, wherein the first repair group circuit is configurable to shift transmission of a third signal from the second one of the external pads to a seventh one of the external pads, and wherein the second repair group circuit is configurable to shift transmission of a fourth signal from the fifth one of the external pads to an eighth one of the external pads.
